(19) United States
(12) Patent Application Publication
(10) Pub. No.: US 2007/0246822 A1
(43) Pub. Date: Oct. 25, 2007

(54) Hard disk drive preamp heat dissipation methods

(76) Inventors: Kerry C. Glover, Rockwall, TX (US); Edgar R. Zuniga-Ortiz, McKinney, TX (US)

Correspondence Address: TEXAS INSTRUMENTS INCORPORATED, P O BOX 655474, M/S 3999, DALLAS, TX, 75265, US

(21) Appl. No.: 11/410,394

(22) Filed: Apr. 25, 2006

(51) Int. Cl. H01L 23/34

(52) U.S. Cl. 257/706; 257/E23.11

(57) ABSTRACT

A heatsink architecture employing a combination of stiffeners and flex substrate to improve the sinking of heat from the integrated circuit. The stiffener may be employed in numerous locations, including above the integrated circuit, or interposed between the integrated circuit and an e-block. The flex substrate may be interposed between the integrated circuit and the stiffener, while in other embodiments the integrated circuit is directly coupled to the e-block via heat conductive epoxy and the like. Solder balls may be employed to connect the flex substrate to integrated circuit. The flex substrate may take different forms, and may or may not be connected to the e-block. The flex substrate may be connected directly to the e-block, or connected via an e-pin extending through layers including the flex substrate and/or the stiffener.

### FIELD OF THE INVENTION

The present invention is generally directed to integrated circuit packaging, and more particularly to dissipating heat from integrated circuits.

### BACKGROUND OF THE INVENTION

Integrated circuits generate heat during operation. In some cases, the heat is excessive due to the high power being passed through the device, high switching speeds and so forth.

Integrated circuits that generate a significant amount of heat requiring dissipation are know to employ either through conduction or convection techniques, with heatsinks commonly being employed for conductively dissipating heat. Different architectures employing heatsinks offer respective advantages and disadvantages, and are sometimes specific to the type of integrated circuit being cooled.

There is desired an improved architecture for employing a heatsink to conductively dissipate heat from an integrated circuit.

### SUMMARY OF INVENTION

The present invention achieves technical advantages as a heatsink architecture employing a combination of a stiffener and a flex substrate to improve the sinking of heat from the integrated circuit. The stiffener may be employed in numerous arrangements, including being disposed above the integrated circuit, or interposed between the integrated circuit and an e-block. The e-block depicted in FIGS. 1 through 9, could be the arm that holds the read/write head on a hard disk drive. The flex substrate is typically mounted on top of the arm. The pre-amp IC is mounted on the flex substrate that is subsequently mounted over the read/write head (e-block). The read/write arm in this case also performs the function of a heat sink.

The flex substrate may be interposed between the integrated circuit and the stiffener, while in other embodiments the integrated circuit may be directly coupled to the e-block via heat conductive epoxy and the like, or via the stiffener. Solder balls may be employed to connect the flex substrate to integrated circuit. The flex substrate may take different forms, and may or may not be thermally coupled to the e-block. The flex substrate may be connected directly to the e-block, or thermally connected via an e-pin extending through layers including the flex substrate and/or the stiffener.

### BRIEF DESCRIPTION OF THE DRAWINGS

FIG. 1 depicts one embodiment of the present invention whereby the stiffener is mounted above an integrated circuit die and connected thereto via a flex substrate and solder balls;

FIG. 2 is another embodiment of the present invention similar to the embodiment of FIG. 1 whereby the flex substrate is directly coupled to the e-block; and the backside of the chip is directly mounted on top of the e-block allowing for maximum heat dissipation;

FIG. 3 is yet another embodiment of the present invention whereby the stiffener is interposed between the die and the e-block, having a flex substrate interposed between the die and the stiffener, and including a slug/heatsink mounted on top of the die;

FIG. 4 is another embodiment of the invention whereby the die is directly connected to the e-block, whereby the flex substrate has an opening allowing direct connection of the die to the e-block, and being interposed between a heatsink/lead frame;

FIG. 5 depicts yet another embodiment whereby the lead frame is shaped as a die paddle with wings;

FIG. 6 depicts an embodiment whereby the stiffener is interposed between the die and the e-block and has an upwardly extending hump directly connecting to the die and encompassed by the flex substrate;

FIG. 7 depicts an embodiment having a heavy gauge wire connecting a heatsink on top of the die to e-block via a heat conductive pin or screw;

FIG. 8 depicts the e-block having an upwardly extending hump directly connecting to the die and encompassed by a flex substrate; and

FIG. 9 is another embodiment depicting a stiffener interposed between the die and e-block, and encompassed by the flex substrate.

### DETAILED DESCRIPTION OF THE PRESENT INVENTION

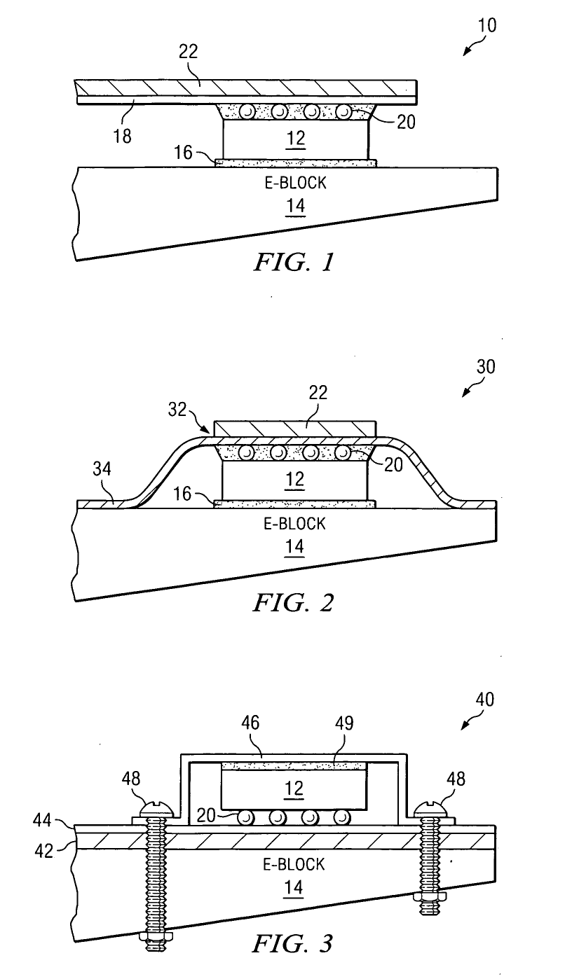

Referring now to FIG. 1, there is generally shown at 10 a first embodiment of the present invention seen to include an integrated circuit die 12 directly connected to an e-block 14 via a heat conductive epoxy layer 16. Disposed over die 12 is a flex substrate 18 connected thereto via solder balls 20. The flex substrate 18 is interposed between a heat conductive stiffener 22 and the die 12, whereby the stiffener acts as a heat sink. The stiffener is made out of a heat conductive material, and is preferably metal, although other non-metallic heat conductive materials are envisioned. The combination of the die 12 directly connected to the heat conductive e-block 14 via epoxy layer 16 and to the stiffener 22 thereabove via the flex substrate 18 provides a very efficient system for conductively sinking heat from the integrated circuit 12 during operation. The flex substrate 18 is flexible and malleable and thus provides a good thermal and mechanical interface to both the solder balls 20 upon heating, as well as to the stiffener 22.

Referring now to FIG. 2, there is shown another embodiment of the present invention at 30, whereby like numerals refer to like elements. Embodiment 30 is similar to embodiment 10 in FIG. 1, whereby the flex substrate 32 employed between the stiffener 22 and the die 12 has contoured leads 34 extending downwardly and directly connected to the e-block 14 each side of die 12 to provide a method of dissipating the heat from stiffener 22 to the e-block 14. The leads 34 of the flex substrate 32 provide an efficient means for drawing heat from the stiffener 22 from above the die 12 to the e-block 14, which e-block 14 thereby sinks a majority of the heat dissipated by die 12.

Referring now to FIG. 3 there is shown at 40 another embodiment of the present invention wherein like numerals refer to like elements. In this embodiment, a stiffener 42 is uniformly disposed upon the e-block 14, and is interposed between the upper surface of e-block 14 and a lower surface of flex substrate 44 as shown. The integrated circuit 12 is directly connected to and disposed upon the upper surface of flex substrate 44 via solder balls 20, as shown. Another flex substrate 46, similar to that shown at 32 in FIG. 2, is disposed around and above the die 12, and is mechanically and thermally connected to the upper surface of die 12 via a heat conductive epoxy layer shown at 49. Advantageously, the flex substrate 46 is directly connected to the e-block 14 via one or more heat conductive e-pins or screws 48 extending through flanged ends of flex substrate 46 and into the e-block 14.

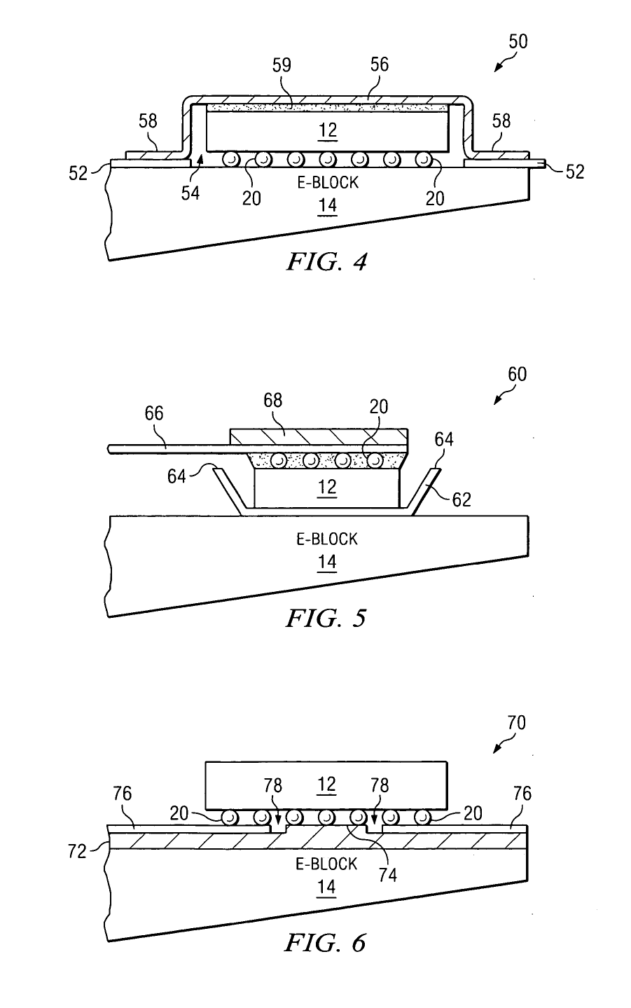

Referring now to FIG. 4, there is shown another embodiment of the present invention at 50 whereby the die 12 is directly connected to the e-block 14 via the solder balls 20. A flex substrate 52 is seen to have an opening 54 encircling the die 12 to permit the direct connection of die 12 to e-block 14. A heatsink/lead frame 56 extends around and over die 12 and is directly connected thereto via a heat conductive epoxy layer 59. The heatsink/lead frame 56 also has laterally extending flange members 58 directly connected to the flex substrate 52 each side of die 12, as shown.

Referring now to FIG. 5, there is shown another embodiment of the invention at 60 whereby a lead frame die paddle 62 having wings 64 receives the die 12 disposed thereupon via a heat conductive epoxy layer 66. This winged lead frame die paddle 62 is disposed upon 3-block 14 which further helps to dissipate heat generated by the die 12 to both the ambient, as well as to the e-block 14. In this embodiment a flex substrate 66 is disposed over and upon die 12, and is interposed between a stiffener 68 and the die 12 as shown.

Referring now to FIG. 6, there is shown yet another embodiment of the present invention at 70 whereby a stiffener layer 72 is interposed between e-block 14 and the die 12, and further including a centrally located and upwardly extending portion 74, shown as a hump, making direct contact with the die 12 via solder balls 20. A flex substrate 76 is disposed upon the stiffener 72, and has an opening 78 encircling the raised portion 74 allowing the stiffener to directly connect to the bottom side of the die 12. In this embodiment, the die 12 dissipates heat to the e-block 14 via the stiffener portion 74, as well as via the underlying flex substrate 76 and stiffener 72 disposed between the perimeter of die 12 and the e-block 14.

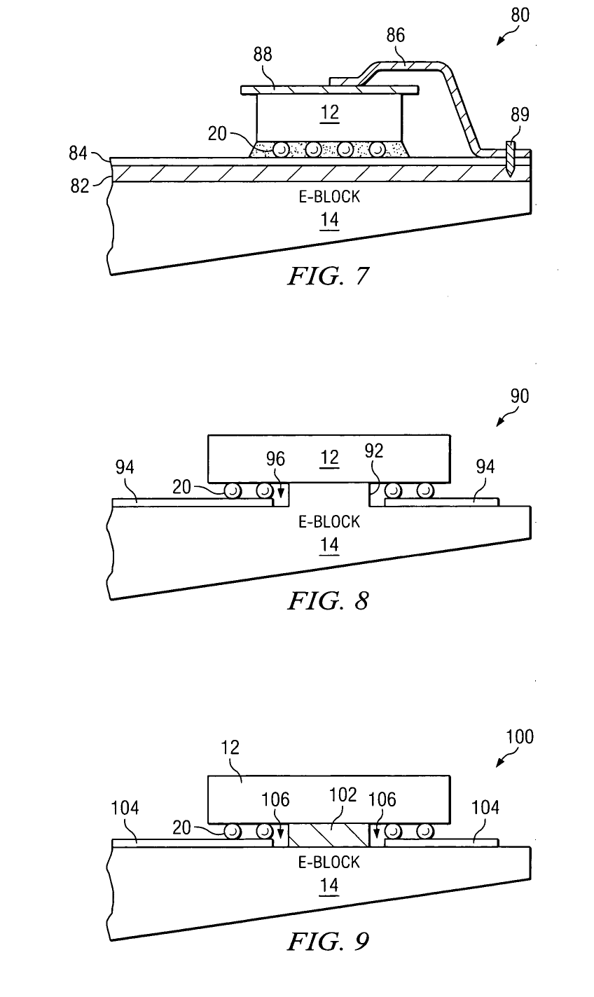

Referring now to FIG. 7 there is shown an embodiment whereby a stiffener 82 is disposed upon the e-block, whereby a flex substrate 84 is disposed thereupon. The die 12 is directly connected to the flex substrate 84 and dissipates heat via the flex substrate 84 and stiffener 82 to the e-block 14. In addition, a heavy gauge wire 86 is connected to a heatsink 88 disposed upon the die 12, and extends to and makes thermal contact with the substrate 84. This end of the wire 86 is also directly connected to the stiffener 82 via a heat conductive pin 89 as shown.

Referring now to FIG. 8 there is shown another embodiment of the present invention at 90, whereby the e-block 14 itself has a raised portion 92 also comprising a stiffener and making direct contact with the underside of die 12 disposed thereupon via a heat conductive paste. A flex substrate 94 is disposed upon the e-block 14, and has an opening 96 encircling the raised portion 92 to permit the direct connection of the die 12 to e-block 14, as shown.

Referring now to FIG. 9, there is shown at 100 another embodiment of the present invention similar to the embodiment of FIG. 8, whereby a slug or stamped stiffener 102 is disposed upon the e-block 14 via a heat conductive paste. The die 12 is directly connected upon the slug or stiffener 102 via heat conductive paste as well. A flex substrate 104 is disposed upon the e-block 14 and has an opening 106 encompassing the slug or stiffener 102 to permit the direct connection of the die 12 to the slug or stiffener 102 as shown. The slug 102 may comprise of copper or other thermally conductive materials.

The various embodiments of the present invention provide improved heatsinking of an integrated circuit 12 to conductively dissipate heat therefrom. Flex substrates and stiffeners are employed in different configurations to increase the sinking of heat from integrated circuit 12 to the stiffener, as well as to the e-block 14. Heat conductive pins may be utilized to directly connect heatsinks and/or stiffeners to the e-block to further enhance the dissipation of heat to the e-block 14.

Though the invention has been described with respect to a specific preferred embodiment, many variations and modifications will become apparent to those skilled in the art upon reading the present application. It is therefore the intention that the appended claims be interpreted as broadly as possible in view of the prior art to include all such variations and modifications.

What is claimed is:

1. A package, comprising
a thermally conductive e-block;
an integrated circuit disposed over the e-block and thermally coupled thereto;
a thermally conductive stiffener; and
a thermally conductive flex substrate interposed between the integrated circuit and the stiffener.

2. The package as specified in claim 1 wherein the stiffener and flex substrate are disposed over the integrated circuit.

3. The package as specified in claim 1 wherein the stiffener and flex substrate are disposed between the integrated circuit and the e-block.

4. The package as specified in claim 2 wherein the flex substrate extends to and is thermally coupled to the e-block.

5. The package as specified in claim 3 further comprising a heatsink disposed over the integrated circuit, wherein the heatsink is thermally connected to the e-block.

6. The package as specified in claim 5 wherein a pin extends through the flex substrate and the stiffener and into the e-block.

7. The package as specified in claim 2 further comprising a lead frame disposed between the integrated circuit and the e-block.

8. The package as specified in claim 7 wherein the lead frame has wings extending upwardly above the e-block.

9. The package as specified in claim 3 wherein the flex substrate has an opening, and the e-block is thermally coupled to the die via the opening to the integrated circuit.

10. The package as specified in claim 9 wherein the e-block has an upwardly extending portion disposed through the flex substrate opening.

11. The package as specified in claim 9 wherein the e-block is directly coupled to the integrated circuit.

12. The package as specified in claim 9 wherein a portion of the stiffener is disposed in the flex substrate opening and is interposed between the integrated circuit and the e-block.

13. The package as specified in claim 12 wherein a portion of the stiffener is also disposed between the flex substrate and the e-block.

14. The package as specified in claim 12 wherein the stiffener is integral to the e-block within the flex substrate opening.

15. The package as specified in claim 3 further comprising a heatsink disposed upon the integrated circuit, and an elongated thermally conductive member extending between the heatsink and the flex substrate.

16. The package as specified in claim 3 further comprising a heatsink disposed upon the integrated circuit, and an elongated thermally conductive member extending between the heatsink and the stiffener.

17. The package as specified in claim 3 further comprising a heatsink disposed upon the integrated circuit, and an elongated thermally conductive member extending between the heatsink and the e-block.

18. The package as specified in claim 15 wherein the member comprises a wire.

19. The package as specified in claim 15 wherein the heatsink comprises a slug.

20. The package as specified in claim 1 wherein the stiffener comprises a metal material.
